(19) United States
(12) Patent Application Publication
(10) Pub. No.: US 2026/0223445 A1
(43) Pub. Date: Jul. 30, 2026

(54) DEVICES AND METHODS FOR METAL RESISTANCE REDUCTION USING DAMASCENE PROCESSES IN FORMING A BACKSIDE CONTACT STRUCTURE

(71) Applicant: Samsung Electronics Co., Ltd., Suwon-si (KR)

(72) Inventors: Byounghoon Kim, Rexford, NY (US); Sangshin Jang, Rexford, NY (US); Wonkeun Chung, Clifton Park, NY (US); Kang-ill Seo, Albany, NY (US)

(21) Appl. No.: 19/339,677

(22) Filed: Sep. 25, 2025

Related U.S. Application Data
(60) Provisional application No. 63/750,500, filed on Jan. 28, 2025.

(51) Int. Cl. H10D 84/83; H10D 30/00; H10D 30/01; H10D 62/10; H10D 64/23; H10D 64/62; H10D 84/01

(52) U.S. Cl. CPC H10D 84/832; H10D 30/019; H10D 30/502; H10D 62/102; H10D 64/251; H10D 64/62; H10D 84/0149

(57) ABSTRACT

A semiconductor device includes a substrate with a gate structure formed thereon and a source/drain region separated from the gate structure. A placeholder region extends into the substrate and is positioned on the source/drain region. A backside contact is formed on the placeholder region, and a backside conductive layer is formed on the backside contact. The backside contact and the backside conductive layer form a monolithic structure. Related methods of forming the semiconductor device are described.

### CROSS-REFERENCE TO RELATED APPLICATIONS

This application claims priority to U.S. Provisional Application No. 63/750,500 Entitled Metal Resistance Reduction Using Damascene PROCESS IN FORMING BACKSIDE CONTACT, filed in the USPTO on Jan. 28, 2025, the disclosure of which is hereby incorporated by reference herein in its entirety.

### TECHNICAL FIELD

The present disclosure generally relates to the field of electronics and, more particularly, to semiconductor devices.

### BACKGROUND

In modern semiconductor manufacturing, the continuous scaling of device dimensions has led to increasingly complex device architectures. Traditional front-side contact schemes face challenges due to space constraints and the need for improved electrical performance. Backside contact architectures have emerged as a promising solution to address these challenges by providing alternative pathways for electrical connections while reducing front-side congestion.

Conventional contact formation methods often suffer from various limitations including poor interface quality, complex fabrication processes, and suboptimal electrical characteristics. There is a continuing need for improved semiconductor device structures and manufacturing methods that can provide better electrical performance, simplified processing, and enhanced reliability.

### SUMMARY

The present inventive concepts provide improved damascene fabrication methods that reduce or eliminate barrier metal layers (BML) that contribute to resistance in backside contact structures. Conventional backside contacts may use a barrier metal layer between the backside contact and backside metal lines, which may generate unwanted contact resistance. According to some embodiments, trenches may be formed for the placeholder, backside contact, and backside metal lines simultaneously using damascene processes. These structures may be filled with a same conductive material (e.g., tungsten, copper, etc.) to create a continuous metal grain structure without barrier layers. According to some embodiments, the placeholder may be filled with a conductive material (e.g., tungsten), and then the backside contact and backside metal lines may be filled with a different conductive material (e.g., copper), which eliminates the barrier metal layer between the placeholder and source/drain region. The approaches described herein may reduce contact resistance by minimizing or eliminating the barrier metal layers that impede current flow, while utilizing various damascene process techniques including single damascene, dual damascene, and/or semi-damascene methods for improved manufacturing efficiency and electrical performance.

Various embodiments are directed towards a semiconductor device that includes a substrate, a gate structure on the substrate, a source/drain region separated from the gate structure, a placeholder region that extends into the substrate and is on the source/drain region, a backside contact on the placeholder region, and a backside conductive layer on the backside contact. The backside contact and the backside conductive layer are a monolithic structure.

According to some embodiments, the semiconductor device may further include a barrier layer between the source/drain region and the placeholder region. According to some embodiments, the barrier layer may extend on a first surface of the placeholder region, a second surface of the placeholder region, and a third surface of the placeholder region, may extend on a first surface of the backside contact, a second surface of the backside contact, and a third surface of the backside contact, and may extend on a first surface of the backside conductive layer, a second surface of the backside conductive layer, and a third surface of the backside conductive layer. The first surface of the placeholder region, the first surface of the backside contact, and the first surface of the backside conductive layer may be parallel to a first surface of the substrate.

According to some embodiments, a width of the backside conductive layer may be greater than a width of the backside contact. According to some embodiments, the width of the backside contact may be greater than a width of the placeholder region. According to some embodiments, the placeholder region, the backside contact, and the backside conductive layer comprise the monolithic structure. According to some embodiments, the semiconductor device may further include a barrier layer between the backside contact and the placeholder region. According to some embodiments, the placeholder region may directly contact the source/drain region. According to some embodiments, the placeholder region may have a curved lower surface that extends into the backside contact. According to some embodiments, the placeholder region may have a first conductive material that is different from a second conductive material of the backside contact. According to some embodiments, the backside conductive layer may have the second conductive material.

According to some embodiments, the backside conductive layer may directly contact the backside contact without a barrier layer therebetween. According to some embodiments, a surface of the backside conductive layer may be coplanar with a surface of an insulating layer that is on the substrate, and a surface of the backside contact may be coplanar with a surface of the substrate.

Various embodiments may be directed towards a semiconductor device that includes a substrate, a gate structure on the substrate, a source/drain region separated from the gate structure, a placeholder region that extends into the substrate and contacts the source/drain region without a barrier region therebetween, a backside contact on the placeholder region, and a backside conductive layer on the backside contact. The backside contact and the backside conductive layer are a monolithic structure.

According to some embodiments, the placeholder region may be adjacent a first surface of the substrate, and the backside contact may extend into the substrate and may be adjacent to a second surface of the substrate that is opposite of the first surface of the substrate. According to some embodiments, the placeholder region may include a first conductive material that is different from a second conductive material of the backside contact. According to some embodiments, the first conductive material may include tungsten and the second conductive material may have copper.

Various embodiments may be directed towards a method of forming a semiconductor device that includes forming a placeholder region that extends into a substrate of the semiconductor device, forming a source/drain region on the placeholder region, forming a first recess adjacent to the placeholder region, the first recess having a first width and extends from a first surface of the substrate into the substrate, forming an insulating layer in the first recess and on the first surface of the substrate, forming a second recess having a second width that is greater than the first width that extends into the insulating layer to the first surface of the substrate, and forming a first conductive material in the first recess and the second recess.

According to some embodiments, forming the first recess may include etching the substrate and the placeholder region, and forming a barrier layer between the placeholder region and the source/drain region. According to some embodiments, forming the first recess may include forming a barrier layer on a surface of the placeholder region that is opposite the source/drain region, and etching the substrate from the first surface of the substrate to the barrier layer. According to some embodiments, the placeholder region may have a second conductive material that is different from the first conductive material.

### BRIEF DESCRIPTION OF THE DRAWINGS

FIG. 1 is a cross-sectional view of a backside contact structure with an integrated placeholder and a backside contact, according to various embodiments.

FIG. 2 is a cross-sectional view of a backside contact structure with a placeholder, backside contact, and backside metal line, according to various embodiments.

FIG. 3 is a cross-sectional view of a backside contact structure with an integrated placeholder, backside contact, and backside metal line that include a conductive material to form a monolithic structure, according to various embodiments.

FIG. 4 is a cross-sectional view of a backside contact structure with an integrated backside contact and backside metal line, according to various embodiments.

FIGS. 5 to 11 illustrate a method of forming the backside contact of FIG. 4, according to various embodiments.

FIGS. 12 to 20 illustrate a method of forming the backside contact of FIG. 3, according to various embodiments.

FIG. 21, FIG. 22, and FIG. 23 are flowcharts of operations of a method of forming a semiconductor device with a backside contact, according to various embodiments.

### DETAILED DESCRIPTION OF EMBODIMENTS

Example embodiments are described herein with reference to the accompanying drawings, which may include cross-section illustrations that are schematic illustrations of idealized embodiments (and intermediate structures). The sizes and relative sizes of layers and regions may be exaggerated for clarity. Additionally, variations from the shapes of the illustrations as a result, for example, of manufacturing techniques and/or tolerances, are to be expected. The same reference numerals may be used to refer to the same or similar elements in various embodiments, where reference numerals followed by a letter (a, b, c, etc.) may refer to specific instances or variations of the same or similar elements. The dimensions of the figures are not to scale.

Modern semiconductor device fabrication faces increasing challenges in achieving low-resistance electrical connections as device dimensions continue to scale down and circuit complexity increases. In backside contact architectures, some manufacturing approaches typically require the formation of barrier metal layers between different conductive elements to prevent metal diffusion and maintain structural integrity during processing. However, these barrier metal layers may introduce significant electrical resistance that degrades overall device performance, particularly in high-current applications such as power delivery networks and signal routing. The resistance contribution from barrier metal layers may become increasingly problematic as contact dimensions shrink, where the relative impact of interface resistance grows substantially compared to bulk metal resistance. Furthermore, traditional sequential metal deposition and patterning processes may create multiple metal interfaces that may compound resistance issues and increase manufacturing complexity. Embodiments described herein address these fundamental limitations through innovative damascene-based fabrication techniques that enable the formation of backside contact structures with reduced interface resistance while maintaining manufacturing reliability and yield. Specifically, the present inventive concepts arise from the recognition that barrier metal layers reduce device performance due to increased electrical resistance.

The present inventive concepts provide a damascene method which forms one or more holes and trenches for a backside contact that includes a placeholder, a backside contact and backside metal line. Damascene processes employ an inlay approach by first creating openings or trenches, and then filling with conductive material. In some damascene processes, barrier layers, which serve as diffusion barriers, may be needed between different conductive materials and between conductive materials and dielectric substrates for metal diffusion prevention. The present inventive concepts provide damascene fabrication methods that create monolithic conductive structures with reduced or eliminated barrier layers between elements, such as between backside contacts and backside metal lines, or between placeholders and source/drain regions. By forming these elements simultaneously, better structural integrity and performance benefits of damascene processing may be realized, while minimizing the electrical penalties traditionally associated with multiple barrier layer interfaces. Although the term “backside metal line” is used herein, this may be used interchangeably with the term “backside conductive line” or “backside conductive layer”.

In some embodiments, the placeholder and the backside contact may be formed together, whereas in some embodiments, the placeholder, the backside contact, and the backside metal line may be formed together. The placeholder, the backside contact, and the backside metal line may be filled with tungsten (W) or copper (Cu) which may provide a lower contact resistance with a metal grain without a barrier metal layer (BML) therebetween these elements. In some embodiments, the placeholder may be at least partially or completely filled with tungsten, and subsequently the backside contact and the backside metal line may be both at least partially or completely filled with copper. This scheme may reduce resistance since there is not a barrier metal layer between the placeholder and the source/drain region (e.g., SiGe).

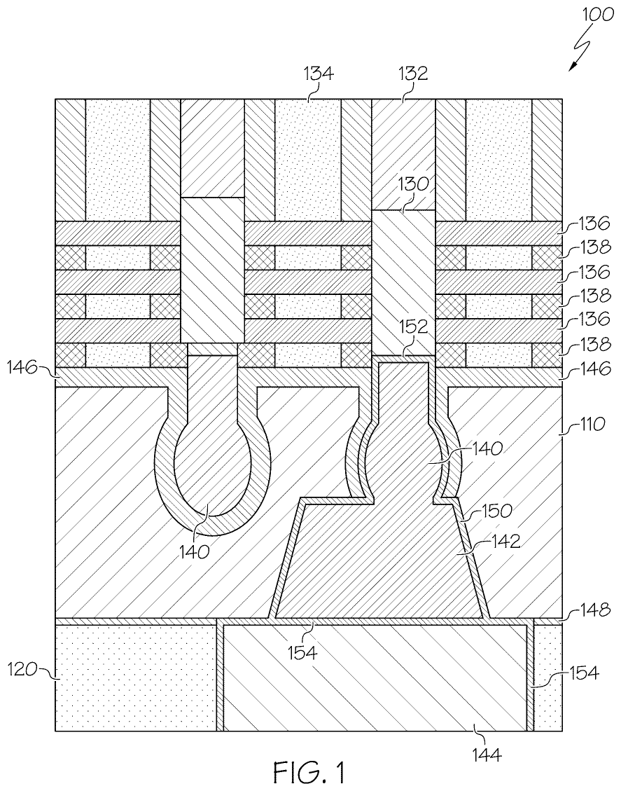

FIG. 1 is a cross-sectional view of a backside contact structure with an integrated placeholder and backside contact, according to various embodiments. A backside contact may be on a backside metal line which may function as a backside power rail or backside signal line with a barrier metal layer between the backside contact and the backside metal line. In some embodiments, a conductive metal such as tungsten (W) may replace the placeholder and the backside contact layer, and the metal forming the backside metal line may include copper (Cu). The barrier metal layer that is between the backside contact structure layer and the backside metal line may generate a contact resistance.

Referring to FIG. 1, the semiconductor device 100 includes a substrate 110, which may serve as the semiconductor material for the device structure. The substrate 110 may additionally or alternatively include or may be formed of insulating materials such as silicon oxide, silicon oxynitride, silicon nitride, silicon carbonitride, silicon boron nitride and/or a low-k dielectric material. The low-k dielectric material may include, for example, fluorine-doped silicon oxide, organosilicate glass, carbon-doped oxide, porous silicon dioxide, porous organosilicate glass, spin-on organic polymeric dielectrics and/or spin-on silicon based polymeric dielectrics. Gate structure 134 may be on an upper surface of substrate 110 and may function as a control electrode for the semiconductor device. Source/drain regions 130 may be formed on the substrate 110 and may be separated from gate structure 134. Source/drain regions 130 may operate as current-carrying terminals for the semiconductor device. The source/drain region 130 may be electrically connected to the channel layers 136. Each of the source/drain regions 130 may include a semiconductor layer (e.g., a silicon (Si) layer and/or a silicon germanium (SiGe) layer) and may additionally include dopants in the semiconductor layer. For example, each of the source/drain regions 130 may include an epitaxial semiconductor layer having dopants (i.e., impurities) therein.

The semiconductor device 100 may include a placeholder region 140, which extends into substrate 110 and is on source/drain region 130. As shown in FIG. 1, placeholder region 140 may have curved side surfaces and may extend into the backside contact 142. A lower portion of placeholder region 140 may be wider than an upper portion of the placeholder region 140. The lower portion of placeholder region 140 may be wider than the source/drain region 130. Backside contact 142 may be on placeholder region 140 and may extend into substrate 110. The backside contact 142 may provide electrical connectivity from the backside of the device to the source/drain region 130 and/or channel layers 136. A backside conductive layer 144 may be on the backside contact 142, and together with backside contact 142, may form a conductive structure that provides electrical connection and/or carry current to the semiconductor device 100.

The cross-sectional view of FIG. 1 illustrates the three-dimensional relationship and vertical integration of the backside contact architecture. According to various embodiments, electrical connectivity is established from the backside conductive layer 144, through backside contact 142 and placeholder region 140, to source/drain region 130, for efficient current flow and device operation in the semiconductor structure.

The semiconductor device 100 includes multiple insulating layers, including insulating layers 132, 138, 146, and 148, which provide electrical isolation between various components and may prevent unwanted current leakage paths. Barrier layers 150, 152, and 154 are between various components to control material diffusion and maintain structural integrity during device operation and formation. The barrier layer may include materials such as titanium nitride, tantalum nitride, or other suitable barrier materials that prevent unwanted material migration. Insulating layer 132 is on the source/drain region 130. Insulating layer 138 is between a lowermost one of the channel layers and insulating layer 146. Insulating layers 138 and 146 may be made of materials with different dielectric constants. Insulating layer 146 may extend into a trench or recess that extends into the substrate 110. The placeholder may be formed on the insulating layer 146. Insulating layer 148 may be between the substrate 110 and insulating layer 120. Insulating layer 148 may be coplanar with a top portion of third barrier layer 154. First barrier layer 152 may be between source/drain region 130 and placeholder region 140. Second barrier layer 150 may be between the substrate 110 and the backside contact 142. Second barrier layer 150 may extend from the first barrier layer 152 and also extend along edges or sidewalls of the placeholder region 140. Second barrier layer 150 may be between the placeholder region 140 and insulating layer 146. Third barrier layer 154 may extend on top and side surfaces of the backside metal line 144. Third barrier layer 154 may be between insulating layer 120 and the backside metal line 144 and may be between the backside metal line 144 and substrate 110.

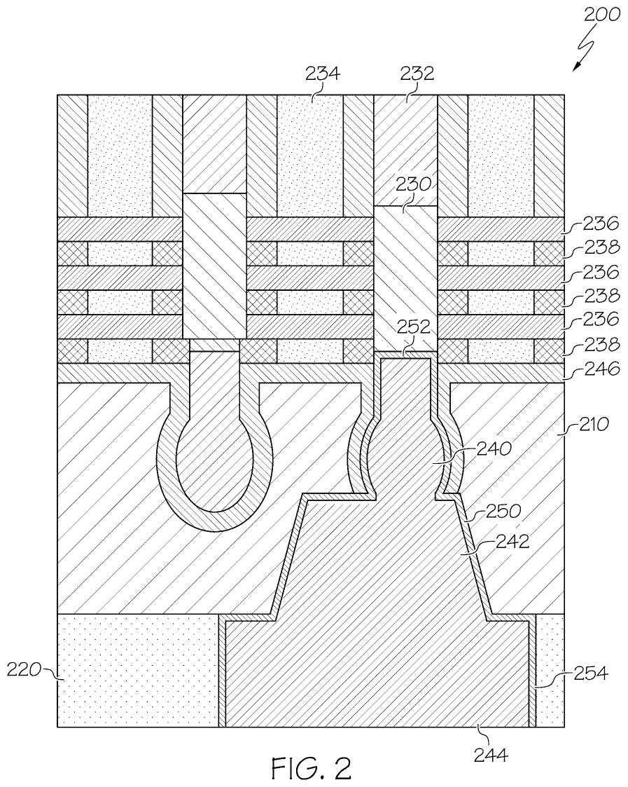

FIG. 2 is a cross-sectional view of a backside contact structure with an integrated placeholder, a backside contact, and a backside metal line, according to various embodiments. A placeholder structure may be on a backside contact, which in turn is on a backside metal line. These three elements are in contact with one another, as shown in FIG. 2. The backside metal line may function as a backside power rail or backside signal line. In contrast with FIG. 1, a barrier metal layer is not between the backside contact and the backside metal line.

Referring to FIG. 2, the semiconductor device 200 includes a substrate 210, which may serve as the semiconductor material for the device structure. The substrate 210 may additionally or alternatively include or may be formed of insulating materials such as silicon oxide, silicon oxynitride, silicon nitride, silicon carbonitride, silicon boron nitride and/or a low-k dielectric material such as, for example, fluorine-doped silicon oxide, organosilicate glass, carbon-doped oxide, porous silicon dioxide, porous organosilicate glass, spin-on organic polymeric dielectrics and/or spin-on silicon based polymeric dielectrics. Gate structure 234 may be on an upper surface of substrate 210 of the semiconductor device 200. Source/drain regions 230 are formed on the substrate 210 and may be separated from gate structure 234. The source/drain region 230 may be electrically connected to the channel regions 236. Each of the source/drain regions 230 may include a semiconductor layer (e.g., a silicon (Si) layer and/or a silicon germanium (SiGe) layer) and may additionally include dopants in the semiconductor layer. For example, each of the source/drain regions 230 may include an epitaxial semiconductor layer having dopants (i.e., impurities) therein.

The semiconductor device 200 may include a placeholder region 240, which extends into substrate 210 and is on source/drain region 230. As shown in FIG. 2, placeholder region 240 may have a generally cylindrical or bottle-shaped configuration with a wider lower portion extending into the substrate 210. The placeholder region 240 may have a curved or bulbous lower portion that provides increased contact area. Backside contact 242 may be formed on a lower surface of the placeholder region 240, extending through the substrate 210. The backside contact 242 may provide electrical connectivity from the backside of the device to the source/drain regions 230 and/or channel regions 236. A backside conductive layer 244 may be on the backside contact 242, and together with backside contact 242, may form a conductive structure that provides electrical connection and carries current to the semiconductor device 200.

The semiconductor device 200 includes multiple insulating layers, including insulating layers 232, 238, 246, and 248, which provide electrical isolation between various components and may prevent unwanted current leakage paths. Barrier layers 250, 252, and 254 are between various components to control material diffusion and maintain structural integrity during device operation and formation. The semiconductor device 200 includes multiple stacked channel regions 236 that are separated by insulating layers 238. Each channel region 236 may be formed of a semiconductor material and may be controlled by the gate structure 234. The gate structure 234 extends vertically to control multiple channel regions 236 simultaneously, forming a three-dimensional transistor structure. Insulating layer 232 may be adjacent to or on the source/drain regions 230. The channel regions 236 are arranged in a stacked configuration with insulating layers 238 providing separation between adjacent channel layers. Second barrier layer 250 may surround portions of the placeholder region 240 and backside contact 242 to provide isolation. Third barrier layer 254 may be around the backside metal line 244 to prevent material diffusion and maintain structural integrity. The first barrier layer 252, second barrier layer 250, and third barrier layer 254 may be portions of a continuous (e.g., integral) barrier layer.

Still referring to FIG. 2, a damascene method may be used to form trenches for the backside contact 242 and the placeholder 240 in one process. Forming the trenches for the backside contact 242 and the placeholder 240 at the same time may improve efficiency of manufacturing the semiconductor device 200.

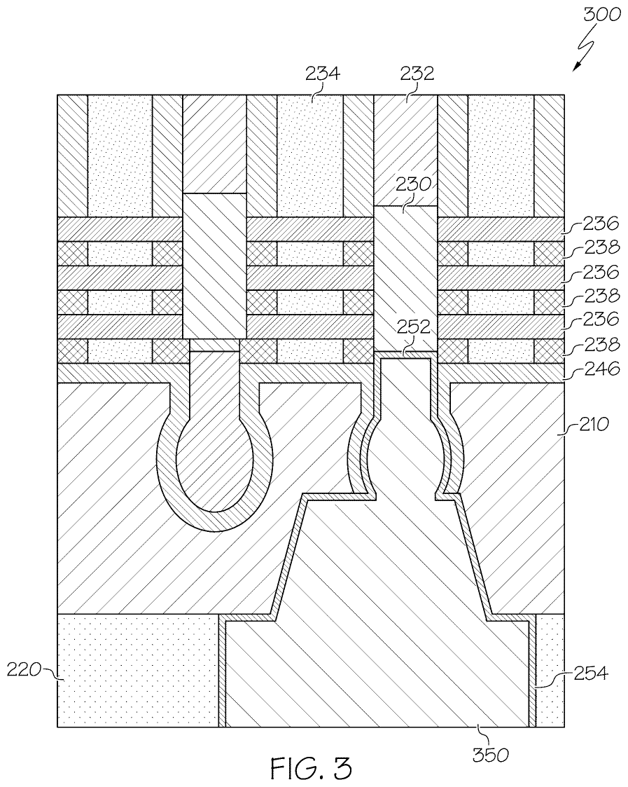

FIG. 3 is a cross-sectional view of a backside contact structure with an integrated placeholder, backside contact, and backside metal line, according to various embodiments. FIG. 3 will be described by focusing on differences to FIG. 2, such that common features may not be described again, in the interest of brevity. The placeholder 240, backside contact 242, and the backside metal line 244 may be partially or completely filled with a conductive material 350 such as tungsten (W) or copper (Cu) to form a monolithic structure. Other conductive materials may be used instead of tungsten (W) or copper (Cu). The monolithic structure without barrier layers between the placeholder 240, backside contact 242, and the backside metal line 244 of semiconductor device 300 provides a reduced contact resistance compared to semiconductor device 100 of FIG. 1, which has a barrier layer 154 between the backside contact 142, and the backside metal line 144.

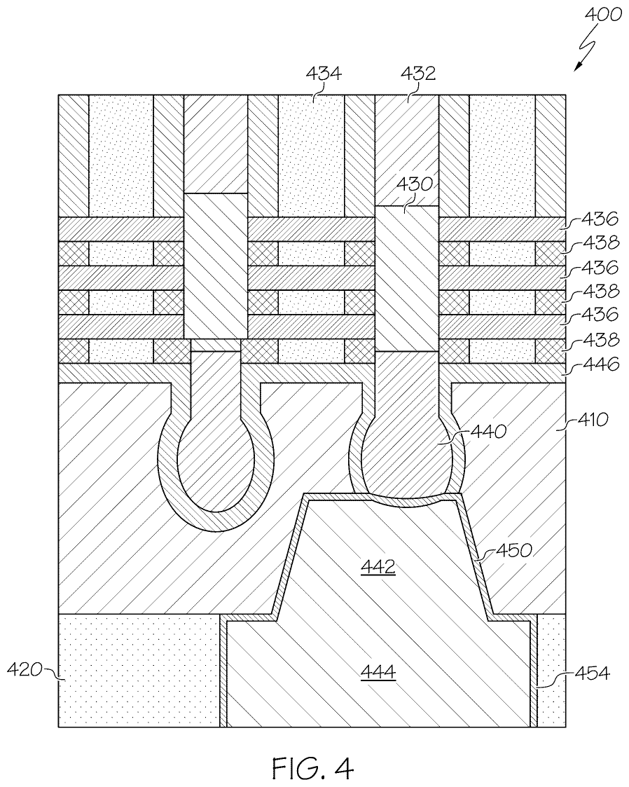

FIG. 4 is a cross-sectional view of a backside contact structure with an integrated backside contact and backside metal line, according to various embodiments. A backside contact may be on a backside metal line, which may function as a backside power rail or backside signal line. A placeholder may be on the backside contact with a barrier metal layer between the backside contact and the placeholder. A conductive metal such as tungsten (W) may replace the placeholder, and the conductive metal forming the backside contact layer and the backside metal line may include a different conductive material such as copper (Cu). The lack of a barrier metal layer between the backside contact and the backside metal line may reduce the contact resistance in the semiconductor device.

Referring to FIG. 4, the semiconductor device 400 includes a substrate 410, which may serve as the semiconductor material for the device structure. The substrate 410 may include or may be formed of insulating materials such as silicon oxide, silicon oxynitride, silicon nitride, silicon carbonitride, silicon boron nitride and/or a low-k dielectric material such as, for example, fluorine-doped silicon oxide, organosilicate glass, carbon-doped oxide, porous silicon dioxide, porous organosilicate glass, spin-on organic polymeric dielectrics and/or spin-on silicon based polymeric dielectrics.

Gate structure 434 may be on an upper surface of substrate 410 and may function as a control electrode for the semiconductor device. The semiconductor device 400 may include a placeholder region 440, which extends into substrate 410 and is on source/drain region 430. Source/drain regions 430 are formed on the substrate 410 and may be separated from gate structure 434. Source/drain regions 430 may operate as current-carrying terminals for the semiconductor device. The source/drain region 430 may be electrically connected to the channel layers 436. Each of the source/drain regions 430 may include a semiconductor layer (e.g., a silicon (Si) layer and/or a silicon germanium (SiGe) layer) and may additionally include dopants in the semiconductor layer. For example, each of the source/drain regions 430 may include an epitaxial semiconductor layer having dopants (i.e., impurities) therein. The source/drain region 430 may be in direct contact with a placeholder 440, without a barrier layer therebetween at the interface between the source/drain region 430 and the placeholder 440.

According to various embodiments, electrical connectivity is established from the backside conductive layer 444, through backside contact 442 and placeholder region 440, to source/drain region 430, for efficient current flow and device operation in the semiconductor device 400.

As shown in FIG. 4, backside contact 442 may have a generally rectangular or trapezoidal cross-sectional shape that extends vertically through multiple layers of the device structure. The placeholder 440 may have a curved or bulbous lower portion. The placeholder 440 may have a substantially uniform width or may have a lower portion that has a greater width than an upper portion of the placeholder 440, as it extends deeper into the substrate 410. Backside contact 442 may be formed below and be electrically connected to the placeholder region 440, extending into the substrate 410 from the bottom surface. The backside contact 442 may provide electrical connectivity from the backside of the device to the source/drain regions 430 and/or channel regions 436. A backside conductive layer 444 may be on the backside contact 442, and together with backside contact 442, may form a conductive structure that provides electrical connection and carries current to the semiconductor device 400.

The semiconductor device 400 includes multiple insulating layers, including insulating layers 432, 438, 446, and 448, which provide electrical isolation between various components and may prevent unwanted current leakage paths. Barrier layers 450 and 454 are between various components to control material diffusion and maintain structural integrity during device operation and formation. The semiconductor device 400 includes multiple stacked channel regions 436 that are separated by insulating layers. Each channel region 436 may be formed of a semiconductor material and may be controlled by the gate structure 434. The gate structure 434 extends vertically through the device stack to control multiple channel regions 436 simultaneously, forming a three-dimensional transistor structure. Insulating layer 432 may be on the source/drain region 430. The channel regions 436 are arranged in a stacked configuration with insulating layers 438 providing separation between adjacent channel layers. Barrier layer 450 may be on a top surface and side surfaces of the backside contact 442. Barrier layer 454 may be on portions of the top surface and on side surfaces of the backside metal line 444 to prevent material diffusion and maintain structural integrity. The barrier layer 450 and barrier layer 454 may be portions of a continuous (e.g., integral) barrier layer that extends on a top portion and on sidewalls of the backside contact 442 and on a portion of the top surface of backside metal line 444 and on sidewalls of the backside metal line 444.

Insulating layer 420 may be below the device structure to provide additional electrical isolation. Insulating layer 420 may be on side surfaces of the backside metal line 444 with barrier layer 454 therebetween.

The placeholder 440 may be replaced with a conductive material such as tungsten (W). A different conductive material, such as copper (Cu), may be included in the backside contact 442 and/or the backside metal line 444. When forming semiconductor device 400, a conductive material may partially or completely fill the placeholder 440 with a conductive material, and subsequently, the backside contact 442 and the backside metal line 444 may be partially or completely filled together with a different conductive material. Since these placeholder 440 portion and the backside contact 442 and the backside metal line 444 portion are formed in two different steps, the process may be referred to as a dual-damascene process. The lack of a barrier layer between the source/drain region 430 and the placeholder 440 may reduce the overall contact resistance of the semiconductor device 400.

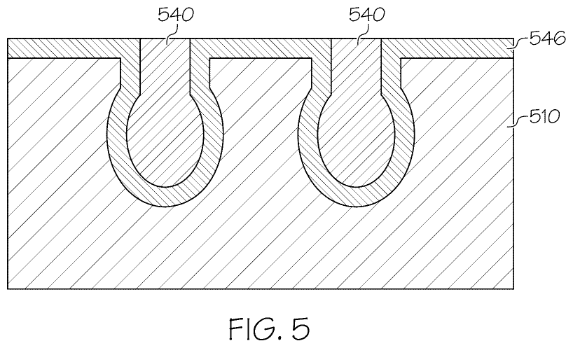

FIGS. 5 to 11 illustrate a method of forming a semiconductor device with the backside contact of FIG. 4, according to various embodiments. FIG. 5 illustrates forming a placeholder in a substrate. Referring to FIG. 5, the method of forming the semiconductor device 400 of FIG. 4 starts by providing a substrate 510. The substrate 510 may serve as the semiconductor material for the semiconductor device and may include materials such as silicon oxide, silicon oxynitride, silicon nitride, silicon carbonitride, silicon boron nitride and/or a low-k dielectric material. The method includes forming one or more trenches that extends into the substrate and then including an insulating layer 546 in the trench that was formed. The method includes forming a placeholder 540 in the one or more trenches that extend into substrate 510. The placeholder regions 540 may have a curved or bulbous lower portion and may have a substantially uniform width or may have a lower portion that has a greater width than an upper portion of the placeholder 540 as it extends into the substrate 510.

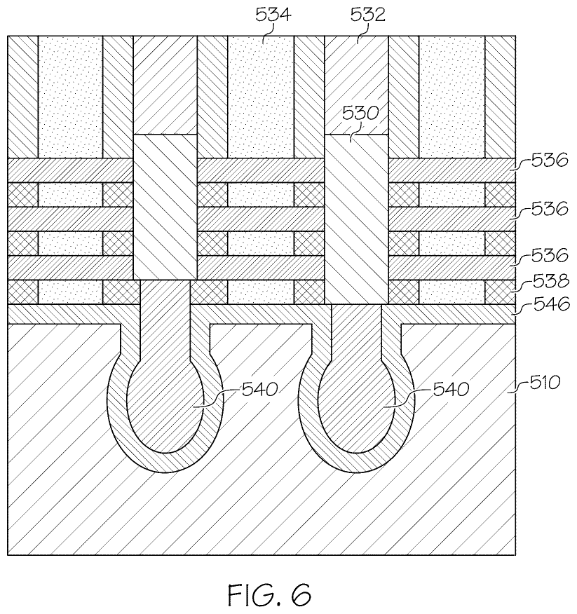

FIG. 6 illustrates the method of forming a semiconductor device including forming of a gate structure, channel layers, and source/drain regions in the semiconductor device. Referring to FIG. 6, a lowermost insulating layer 538 may be formed on the insulating layer 546 that is on the substrate. In some embodiments, insulating layers 538 may be made of a different material and/or may have a different dielectric constant than the material of insulating layer 546. A channel layer 536 is formed on the insulating layer 538. Subsequently, additional channel layers 536 and insulating layers 538 are alternately stacked on one another. In other words, channel regions 536 are separated from one another by the insulating layers 538. Each of the channel regions 536 may be formed of a semiconductor material. Gate structures 534 are formed to extend vertically through the device stack that includes the channel layers 536 and insulating layers 538. The gate structures 534 may extend to the insulating layer 546 that is on the substrate 510. The source/drain region 530 is formed on the placeholder region 540. The source/drain region 530 is directly formed on the placeholder region 540 without a barrier layer therebetween. The lack of the barrier layer therebetween produces a device that has reduced resistance compared to devices that have the barrier layer therebetween. In some embodiments, the source/drain region 530 may have a greater width than the placeholder region 540. Edge lower portions of the source/drain region 530 may be in contact with insulating layer 546.

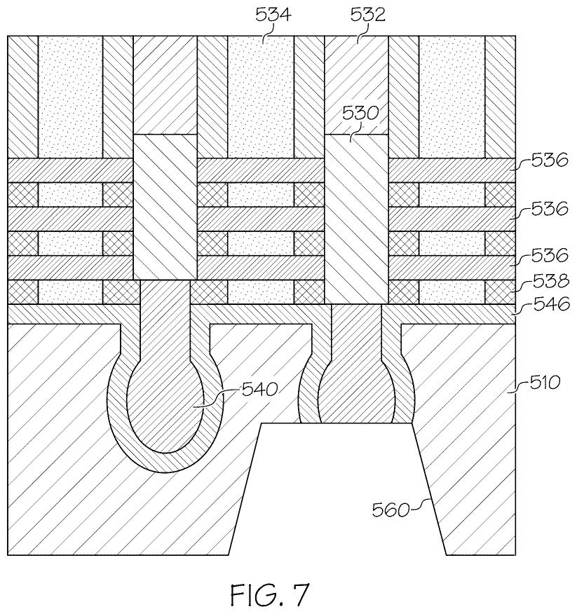

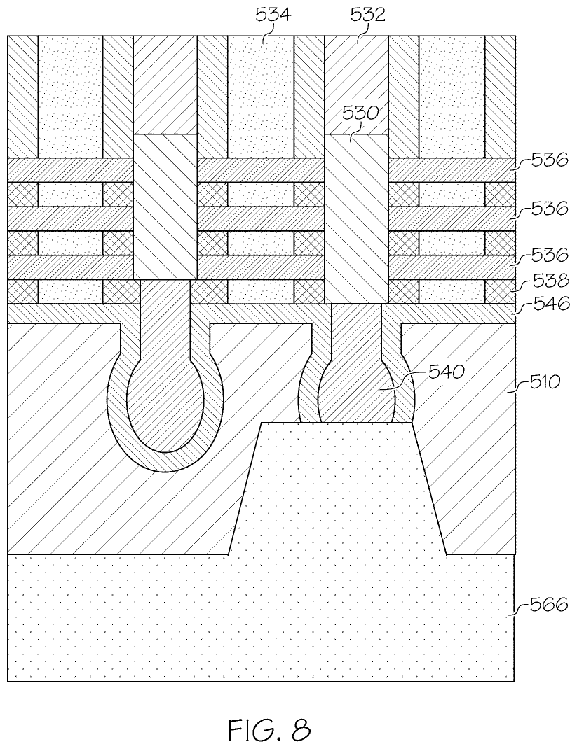

FIG. 7 illustrates the method of forming a semiconductor device including forming a recess for a backside contact structure. Referring to FIG. 7, a trench 560 is formed on the bottom side of the substrate 510, opposite the gate structure 534. The trench 560 extends into the substrate 510 and into a bottom portion of the insulating layer 546 and a bottom portion of the placeholder 540. The surface of the trench that is adjacent to the bottom portion of the placeholder 540 may have a relatively planar shape. In other words, the bottom portion of the placeholder 540 may have a planar shape, after the formation of the trench 560. Trench 560 may have a trapezoidal shape with a bottom portion have a greater width than the top portion of trench 560, with angled sidewalls therebetween. Trench 560 may be formed by etching.

FIG. 8 illustrates the method of forming a semiconductor device that includes providing an insulating layer on the bottom of the semiconductor device. Referring to FIG. 8, an insulating layer 566 may be formed below the device structure to provide additional electrical isolation for the semiconductor device. Insulating layer 566 may extend into the trench 560 to the bottom surface of placeholder 540. Insulating layer 566 may be on side surfaces of the trench 560.

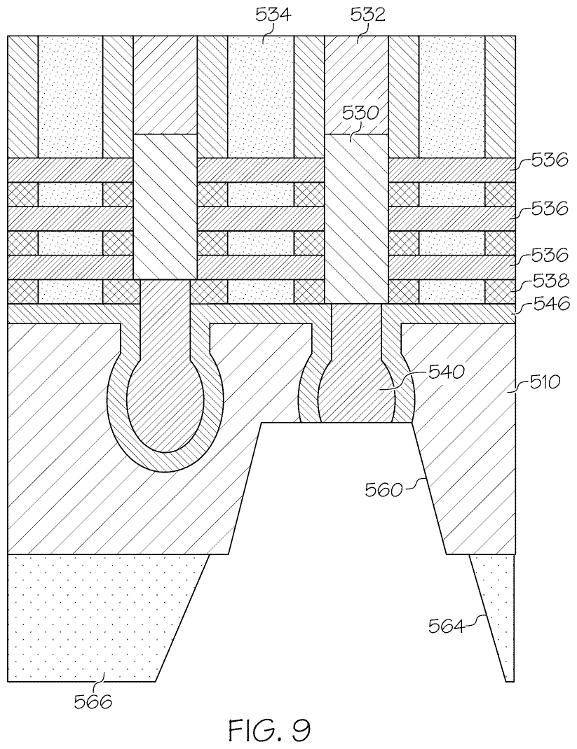

FIG. 9 illustrates the method of forming a semiconductor device that includes forming a second trench. Referring to FIG. 9, first trench 560 may be formed as discussed with respect to FIG. 7 and FIG. 8. A second trench 564 may be formed in the insulating layer 566, using for example, an etching process. A top portion of the second trench 564 may have a width that is greater than a width of the bottom portion of the first trench 560. Second trench 564 may have a trapezoidal shape with a bottom portion having a greater width than the top portion of the second trench 564, with angled sidewalls therebetween. The second trench 564 may extend from a bottom surface of the insulating layer 566 to a bottom surface of substrate 510.

Still referring to FIG. 9, the placeholder 540 may be replaced with a conductive material such as tungsten (W). The conductive material may be introduced into the placeholder 540 through first and second trenches 560 and 564.

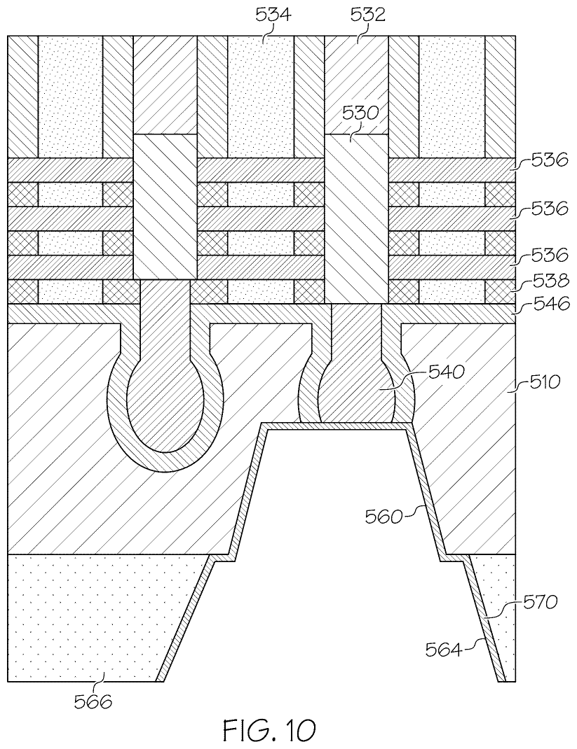

FIG. 10 illustrates the method of forming a semiconductor device that includes forming a barrier layer in the trenches described with respect to FIG. 9. Referring to FIG. 10, a barrier layer 570 is formed in the first trench 560 and the second trench 564. Barrier layer 570 may extend continuously from a bottom portion of insulating layer 566 along both sidewalls of the second trench 564, along both sidewalls of the first trench 560, and along a top portion of first trench 560. The barrier layer may be adjacent and/or in contact with a bottom surface of the placeholder 540, which now includes a conductive material, as described with respect to FIG. 9.

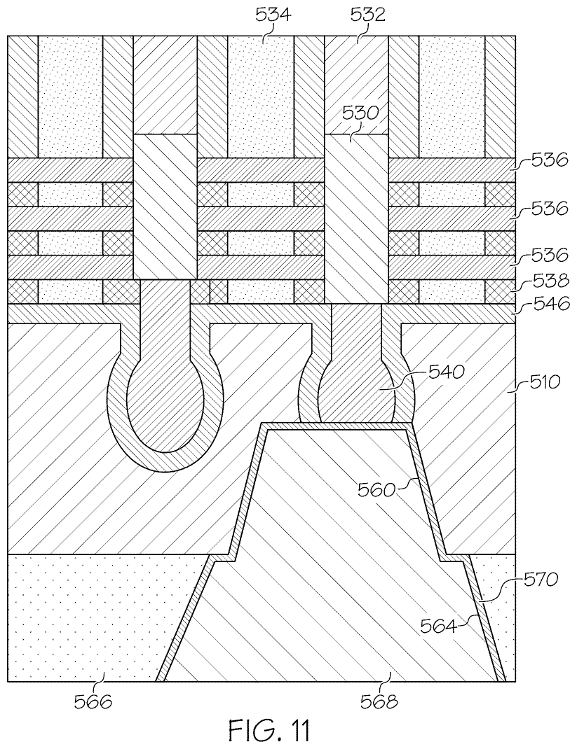

FIG. 11 illustrates the method of forming a semiconductor device that includes forming a conductive backside contact. Referring to FIG. 11, a conductive material 568 is formed in the first trench 560 and the second trench 564. The conductive material 568 is on the barrier layer 570. The conductive material 568 corresponds to the backside contact 442 and the backside metal line 444 of FIG. 4. Thus, the backside contact 442 and the backside metal line 444 are formed at the same time, and include a same conductive material. Compared to the conductive material included in the placeholder 540, a different conductive material may be included in the conductive material 568 that comprises the backside contact and the backside metal line. For example, conductive material 568 may include copper (Cu) whereas the placeholder 540 includes tungsten (W). When forming semiconductor device, the conductive material may partially or completely fill first and second trenches 560 and 564 with the conductive material 568 to form the monolithic backside contact and backside metal line.

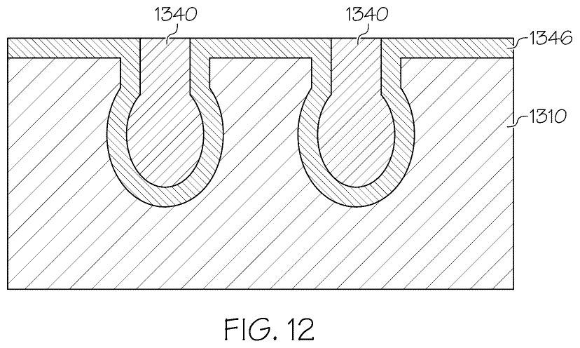

FIGS. 12 to 20 illustrate a method of forming a semiconductor device with the backside contact of FIG. 3, according to various embodiments. FIG. 12 illustrates forming a placeholder in a substrate. Referring to FIG. 12, the method of forming the semiconductor device 300 of FIG. 3 starts by providing a substrate 1310. The substrate 1310 may serve as the semiconductor material for the semiconductor device. The method includes forming one or more trenches that extend into the substrate and then including an insulating layer 1346 on sidewalls and a bottom surface of the trench that was formed. The method includes forming a placeholder 1340 in the one or more trenches that extend into substrate 1310. The placeholder 1340 may have a curved or bulbous lower portion and may have a substantially uniform width upper portion. The placeholder 1340 may have a lower portion that has a greater width than an upper portion of the placeholder 1340 as it extends into the substrate 1310.

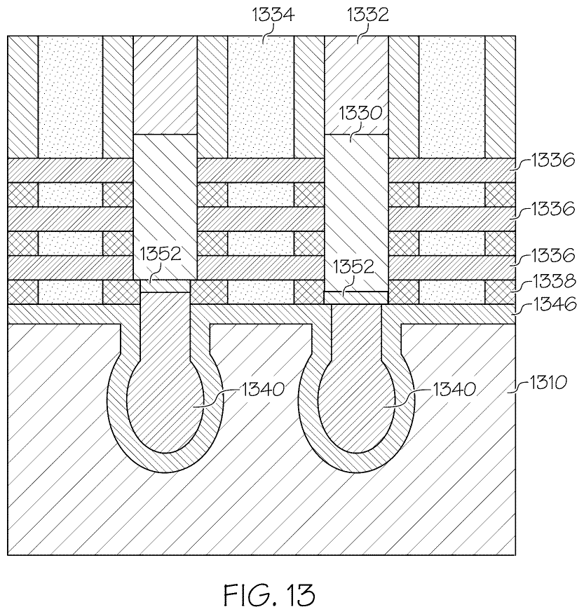

FIG. 13 illustrates the method of forming a semiconductor device including forming of a gate structure, channel layers, and source/drain regions in the semiconductor device. Referring to FIG. 13, a lowermost insulating layer 1338 may be formed on the insulating layer 1346 that is on the substrate. In some embodiments, insulating layers 1338 may be made of a different material and/or may have a different dielectric constant than the material of insulating layer 1346. A channel layer 1336 is formed on the insulating layer 1338. Subsequently, additional channel layers 1336 and insulating layers 1338 are alternately stacked on one another. In other words, channel regions 1336 are separated from one another by the insulating layers 1338. Each of the channel regions 1336 may be formed of a semiconductor material. Gate structures 1334 are formed to extend vertically through the device stack. The gate structures 1334 may extend to the insulating layer 1346 that is on the substrate 1310. A barrier layer 1352 is formed on the placeholder region 1340. A source/drain region 1330 is formed on the barrier layer 1352, opposite the placeholder region 1340. The barrier layer 1352 may include materials such as titanium nitride, tantalum nitride, or other suitable barrier materials.

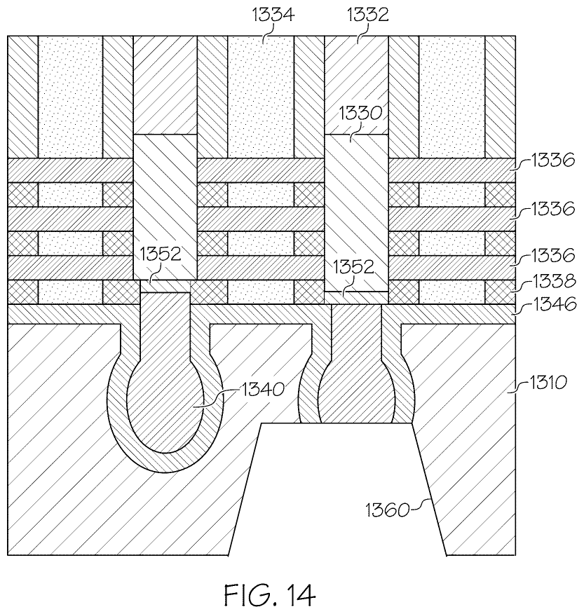

FIG. 14 illustrates the method of forming a semiconductor device including forming a recess for a backside contact structure. Referring to FIG. 14, a trench 1360 is formed on the bottom side of the substrate 1310, opposite the gate structure 1334. The trench 1360 extends into the substrate 1310 and into a bottom portion of the insulating layer 1346 and a bottom portion of the placeholder 1340. The surface of the trench that is adjacent to the bottom portion of the placeholder 1340 may have a relatively planar shape. In other words, the bottom portion of the placeholder 1340 may have a planar shape, after the formation of the trench 1360. Trench 1360 may have a trapezoidal shape with a bottom portion have a greater width than the top portion of trench 1360, with angled sidewalls therebetween.

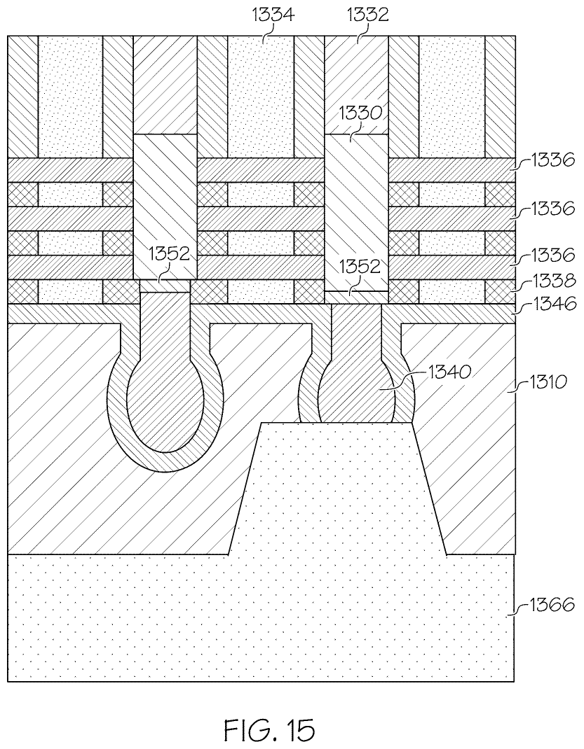

FIG. 15 illustrates the method of forming a semiconductor device that includes providing an insulating layer on the bottom of the semiconductor device. Referring to FIG. 15, an insulating layer 1366 may be provided below the device structure to provide additional electrical isolation for the semiconductor device. Insulating layer 1366 extends into the trench 1360 to the bottom surface of placeholder 1340. Insulating layer 1366 may be on side surfaces of the trench 1360.

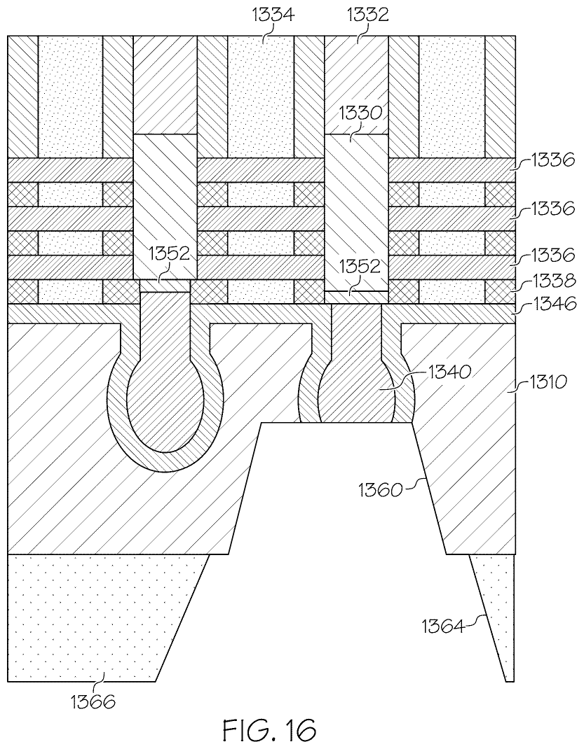

FIG. 16 illustrates the method of forming a semiconductor device that includes forming a second trench. Referring to FIG. 16, first trench 1360 may be formed as discussed with respect to FIG. 14 and FIG. 15. A second trench 1364 may be formed in the insulating layer 1366. A top portion of the second trench 1364 may have a width that is greater than a width of the bottom portion of the first trench 1360. Second trench 1364 may have a trapezoidal shape with a bottom portion having a greater width than the top portion of the second trench 1364, with angled sidewalls therebetween. The second trench 1364 may extend from a bottom surface of the insulating layer 1366 to a bottom surface substrate 1310. The first trench 1360 and the second trench 1364 may have a double-stacked trapezoidal shape. The first trench 1360 and the second trench 1364 may be formed using etching processes.

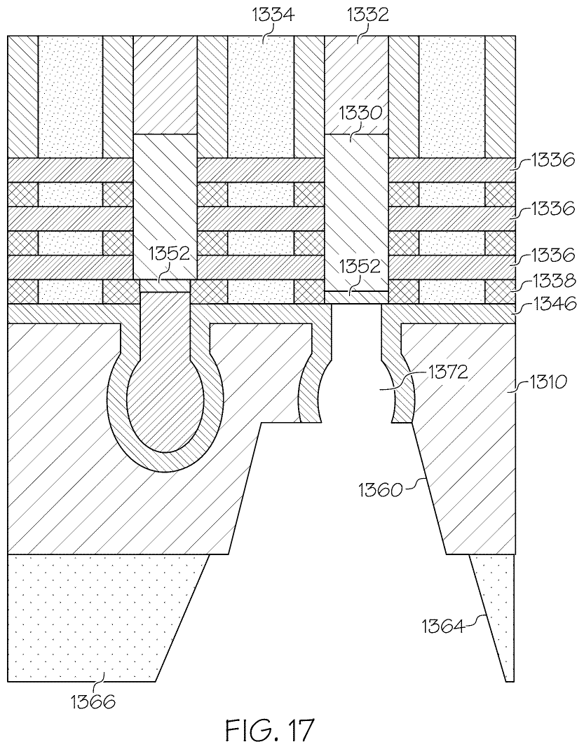

FIG. 17 illustrates the method of forming a semiconductor device that includes etching the placeholder. Referring to FIG. 17, the placeholder 1340 of FIG. 16 may be etched (e.g., removed) to reveal an intermediary gap 1372. The etching process may use barrier layer 1352 and insulating layer 1346 as etch stop layers. In some embodiments, an etch stop layer (not shown) may be included on the insulating layer 1346 before forming the placeholder 1340.

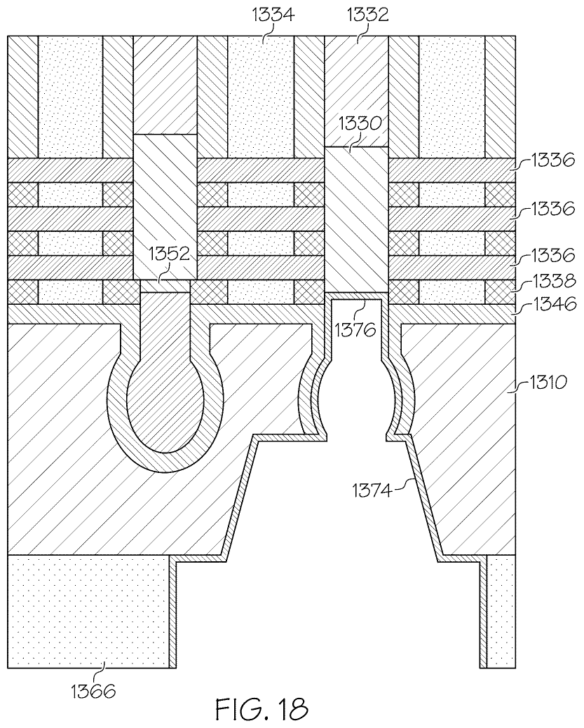

FIG. 18 illustrates the method of forming a semiconductor device that includes forming a conductive backside contact. Referring to FIG. 18, barrier layer 1374 is formed in the first trench 1360, the second trench 1364, and in the etched out portion formerly occupied by the placeholder. In some embodiments, instead of forming barrier layer 1352 as shown in FIG. 13, a barrier layer 1376 may be formed on a bottom portion of source/drain region 1330. Barrier layer 1374, together with barrier layer 1352 of FIG. 13 or barrier layer 1376 of FIG. 18, may extend continuously from a bottom portion of insulating layer 1366 along both sidewalls of the second trench 1364, along both sidewalls of the first trench 1360 and along sidewalls of the placeholder region. The barrier layer may be adjacent and/or in contact with a bottom surface of the source/drain region 1330.

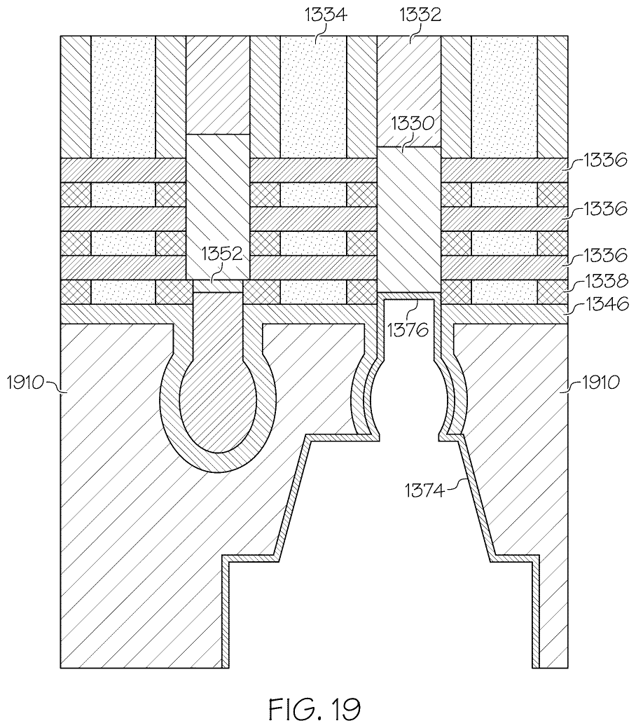

FIG. 19 illustrates the method of forming a semiconductor device that includes a single inter-dielectric layer in the trenches. Referring to FIG. 19, different from the embodiment of FIGS. 15 to 18, a single inter-dielectric layer 1910 may be formed by the damascene process. In other words, the damascene process may deposit the same dielectric film across different vertical layers of the structure. Trenches and barrier layers 1376 and 1374 are formed similar to the embodiments described with respect to FIG. 16 to 18 on the single inter-dielectric layer 1910.

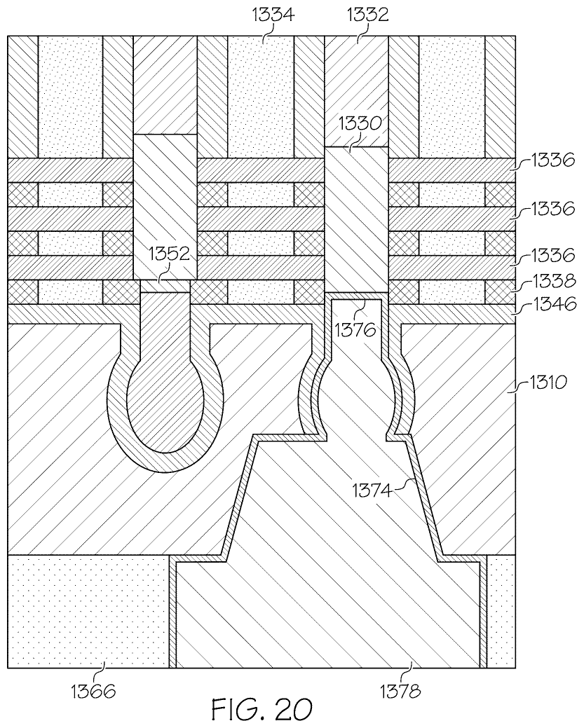

FIG. 20 illustrates the method of forming a semiconductor device that includes forming a conductive backside contact. Referring to FIG. 20, a conductive material 1378 is formed in the first trench 1360, the second trench 1364, and in the placeholder region. The conductive material 1378 is on the barrier layer 1376 and barrier layer 1374. The conductive material 1378 corresponds to the placeholder 240, backside contact 242, and the backside metal line 244 of FIG. 3. Thus, the placeholder 240, the backside contact 242 and the backside metal line 244 are formed in a same process as a monolithic structure, and include a same conductive material. For example, conductive material 1378 may include copper (Cu) or tungsten (W).

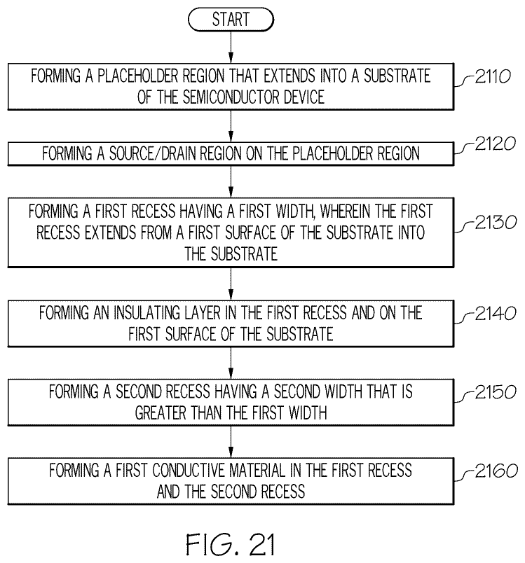

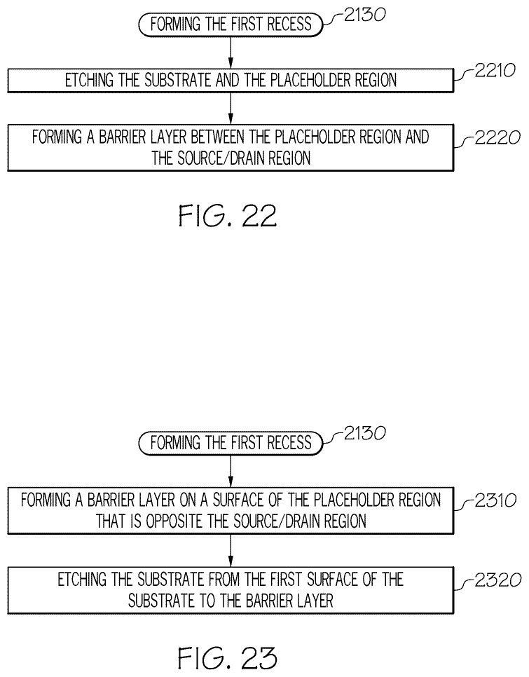

FIG. 21, FIG. 22, and FIG. 23 are flowcharts of operations of a method of forming a semiconductor device with a backside contact, according to various embodiments. Referring to FIG. 21, the process may begin with forming a placeholder region that extends into a substrate of the semiconductor device, at block 2110. The placeholder region may serve as a temporary structure that will later be replaced with a conductive material to establish electrical connectivity. A source/drain region may be formed on the placeholder region, at block 2120. The source/drain region may operate as a current-carrying terminal for the semiconductor device and may include semiconductor layers having dopants therein. The method may continue with forming a first recess having a first width, wherein the first recess extends from a first surface of the substrate into the substrate, at block 2130. The first recess may be formed through selective etching processes that creates an opening or trench for the backside contact structure.

Still referring to FIG. 21, an insulating layer may be formed in the first recess and on the first surface of the substrate, at block 2140. The insulating layer may provide electrical isolation between various components and may prevent unwanted current leakage paths. The insulating layer may include materials such as silicon oxide, silicon nitride, or other suitable dielectric materials. A second recess having a second width that is greater than the first width may be formed, at block 2150. The second recess may be created through additional etching processes that expand the opening to accommodate the backside contact structure. A first conductive material may be formed in the first recess and the second recess, at block 2160. The first conductive material may include copper, tungsten, or other suitable conductive materials that provide low electrical resistance.

Referring to FIG. 22, according to some embodiments, forming the first recess, at block 2130, which corresponds to the same operation described in FIG. 21, may include etching the substrate and the placeholder region, at block 2210. The etching operation may remove portions of the substrate material and the placeholder region to create the desired geometry for the backside contact structure. The etching may be performed using selective dry etching or wet etching techniques that control the removal of material. A barrier layer may be formed between the placeholder region and the source/drain region, at block 2220. The barrier layer may control material diffusion and maintain structural integrity during device operation and formation. The barrier layer may include materials such as titanium nitride, tantalum nitride, or other suitable barrier materials.

Referring to FIG. 23, according to some embodiments, forming the first recess, at block 2130, may include forming a barrier layer on a surface of the placeholder region that is opposite the source/drain region, at block 2310. This barrier layer placement may provide selective material diffusion control at the interface between the placeholder region and subsequent device structures. The barrier layer may be deposited using physical vapor deposition, chemical vapor deposition, or atomic layer deposition techniques to achieve thickness control and uniform coverage. The method may include etching the substrate from the first surface of the substrate to the barrier layer, at block 2320. This etching operation may create the final geometry for the backside contact structure by removing substrate material to the barrier layer, which serves as an etch stop. The etching process may utilize selective chemistry that stops on the barrier layer material while continuing to remove the substrate material, ensuring precise depth control for the backside contact formation.

Various embodiments described herein present semiconductor device fabrication techniques that improve electrical resistance in backside contact structures. A dual damascene process is used to create monolithic conductive structures that eliminate the need for barrier metal layers between some components, thereby reducing contact resistance and improving overall device performance as semiconductor dimensions continue to scale down.

Unless otherwise defined, all terms used herein have the same meaning as commonly understood by one of ordinary skill in the art. Further, all terms should be interpreted as having a meaning that is consistent with their meaning in the context of the relevant art and this disclosure and will not be interpreted in an idealized or overly formal sense unless expressly so defined herein.

While embodiments have been described with respect to semiconductor functions, the embodiments of the present disclosure are not limited. Possible implementations may be embodied in a single integrated circuit, a multi-chip module, a single card, system-on-a-chip, or a multi-card circuit pack. As would be apparent to one skilled in the art, the various embodiments might also be implemented as part of a larger system. Such embodiments of the semiconductor device might be employed in conjunction with, for example, a digital signal processor, microcontroller, field-programmable gate array, application-specific integrated circuit, or general-purpose computer.

The terminology used herein is for the purpose of describing particular embodiments only and is not intended to be limiting of embodiments. The singular forms “a,” “an,” and “the” are intended to include the plural forms as well, unless the context clearly indicates otherwise. The terms “comprises,” “comprising,” “includes” and/or “including” specify the presence of the stated features, steps, operations, elements, components and/or groups, but do not preclude the presence or addition of one or more other features, steps, operations, elements, components and/or groups thereof.

It will be understood that, although the terms “first,” “second,” etc. may be used throughout this specification to describe various elements, these elements should not be limited by these terms. Rather, these terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

The terms “surround” or “cover” or “fill” as used herein may not require completely surrounding or covering or filling the described elements or layers, but may, for example, refer to partially surrounding or covering or filling the described elements or layers. Components or layers described with reference to “overlap” in a particular direction may be at least partially obstructed by one another when viewed along a line extending in the particular direction or in a plane perpendicular to the particular direction.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. The term “connected” may include physical and/or electrical connections.

Spatially relative terms such as “below” or “above” or “upper” or “lower” or “top” or “bottom” or “side” may be used herein to describe a relationship of one element, layer or region to another element, layer or region based on a frame of reference (e.g., a substrate), as illustrated in the figures. It will be understood that these terms are intended to encompass different orientations of the device in addition to the orientation depicted in the figures.

Example embodiments are described herein with reference to the accompanying drawings, which may include cross-section illustrations that are schematic illustrations of idealized embodiments (and intermediate structures). Many different forms and embodiments are possible without deviating from the teachings of this disclosure. Accordingly, the present disclosure should not be construed as limited to the example embodiments set forth herein. As such, it will be understood by those of ordinary skill in the art that various changes in form and details may be made therein without departing from the scope as defined herein. In the drawings, the sizes and relative sizes of layers and regions may be exaggerated for clarity. Additionally, variations from the shapes of the illustrations as a result, for example, of manufacturing techniques and/or tolerances, are to be expected.

Embodiments of the present disclosure are also described with reference to fabrication operations and flowchart diagrams. It will be appreciated that the steps shown in the fabrication operations and flowchart diagrams need not be performed in the order shown.

The above-disclosed subject matter is to be considered illustrative, and not restrictive, and the appended claims are intended to cover all such modifications, enhancements, and other embodiments, which fall within the scope of the present disclosure. Thus, to the maximum extent allowed by law, the scope is to be determined by the broadest permissible interpretation of the following claims and their equivalents, and shall not be restricted or limited by the foregoing detailed description.

What is claimed is:

1. A semiconductor device comprising:
a substrate;
a gate structure on the substrate;
a source/drain region separated from the gate structure;
a placeholder region that extends into the substrate and is on the source/drain region;
a backside contact on the placeholder region; and
a backside conductive layer on the backside contact,
wherein the backside contact and the backside conductive layer are a monolithic structure.

2. The semiconductor device of claim 1, further comprising:
a barrier layer between the source/drain region and the placeholder region.

3. The semiconductor device of claim 2, wherein the barrier layer extends on a first surface of the placeholder region, a second surface of the placeholder region, and a third surface of the placeholder region, extends on a first surface of the backside contact, a second surface of the backside contact, and a third surface of the backside contact, and extends on a first surface of the backside conductive layer, a second surface of the backside conductive layer, and a third surface of the backside conductive layer, and
wherein the first surface of the placeholder region, the first surface of the backside contact, and the first surface of the backside conductive layer are parallel to a first surface of the substrate.

4. The semiconductor device of claim 1, wherein a width of the backside conductive layer is greater than a width of the backside contact, and
wherein the width of the backside contact is greater than a width of the placeholder region.

5. The semiconductor device of claim 1, wherein the placeholder region, the backside contact, and the backside conductive layer comprise the monolithic structure.

6. The semiconductor device of claim 1, further comprising:
a barrier layer between the backside contact and the placeholder region.

7. The semiconductor device of claim 1, wherein the placeholder region directly contacts the source/drain region.

8. The semiconductor device of claim 1, wherein the placeholder region comprises a curved lower surface that extends into the backside contact.

9. The semiconductor device of claim 1, wherein the placeholder region comprises a first conductive material that is different from a second conductive material of the backside contact.

10. The semiconductor device of claim 9, wherein the backside conductive layer comprises the second conductive material.

11. The semiconductor device of claim 1, wherein the backside conductive layer directly contacts the backside contact without a barrier layer therebetween.

12. The semiconductor device of claim 1, wherein a surface of the backside conductive layer is coplanar with a surface of an insulating layer that is on the substrate, and
wherein a surface of the backside contact is coplanar with a surface of the substrate.

13. A semiconductor device comprising:
a substrate;
a gate structure on the substrate;
a source/drain region separated from the gate structure;
a placeholder region that extends into the substrate and contacts the source/drain region without a barrier region therebetween;
a backside contact on the placeholder region; and
a backside conductive layer on the backside contact,
wherein the backside contact and the backside conductive layer are a monolithic structure.

14. The semiconductor device of claim 13, wherein the placeholder region is adjacent a first surface of the substrate, and
wherein the backside contact extends into the substrate and is adjacent to a second surface of the substrate that is opposite of the first surface of the substrate.

15. The semiconductor device of claim 13, wherein the placeholder region comprises a first conductive material that is different from a second conductive material of the backside contact.

16. The semiconductor device of claim 15, wherein the first conductive material comprises tungsten and the second conductive material comprises copper.

17. A method of forming a semiconductor device, the method comprising:
forming a placeholder region that extends into a substrate of the semiconductor device;
forming a source/drain region on the placeholder region;
forming a first recess adjacent to the placeholder region, the first recess having a first width, wherein the first recess extends from a first surface of the substrate into the substrate;
forming an insulating layer in the first recess and on the first surface of the substrate;
forming a second recess having a second width that is greater than the first width, wherein the second recess extends into the insulating layer to the first surface of the substrate; and
forming a first conductive material in the first recess and the second recess.

18. The method of forming the semiconductor device of claim 17, wherein forming the first recess comprises:
etching the substrate and the placeholder region; and
forming a barrier layer between the placeholder region and the source/drain region.

19. The method of forming the semiconductor device of claim 17, wherein forming the first recess comprises:
forming a barrier layer on a surface of the placeholder region that is opposite the source/drain region; and
etching the substrate from the first surface of the substrate to the barrier layer.

20. The method of forming the semiconductor device of claim 17, wherein the placeholder region comprises a second conductive material that is different from the first conductive material.
